(19) United States
(12) Patent Application Publication
(10) Pub. No.: US 2009/0290614 A1
(43) Pub. Date: Nov. 26, 2009

(54) NANO-COMPOSITES FOR THERMAL BARRIER COATINGS AND THERMO-ELECTRIC ENERGY GENERATORS

(75) Inventors: Otto J. Gregory, Wakefield, RI (US); Gustave C. Fralick, Middleburg Heights, OH (US); John D. Wrbanek, Sheffield, OH (US)

Correspondence Address: GAUTHIER & CONNORS, LLP, 225 FRANKLIN STREET, SUITE 2300, BOSTON, MA, 02110, US

(73) Assignee: BOARD OF GOVERNORS FOR HIGHER EDUCATION, STATE OF RHODE ISLAND NAD PROVIDENCE, Providence, RI (US)

(21) Appl. No.: 12/424,131

(22) Filed: Apr. 15, 2009

Related U.S. Application Data
(63) Continuation of application No. PCT/US2007/081778, filed on Oct. 18, 2007.
(60) Provisional application No. 60/852,489, filed on Oct. 18, 2006.

(51) Int. Cl. G01K 17/00; G01K 7/02; C23C 16/06; C23C 14/34; B05D 1/08; B05D 1/36

(52) U.S. Cl. 374/29; 374/179; 427/250; 204/192.15; 427/446; 374/E17.001; 374/E07.004

(57) ABSTRACT

A nano-composite material having a high electrical conductivity and a high Seebeck coefficient and low thermal conductivity. The nano-composite material is capable of withstanding high temperatures and harsh conditions. These properties make it suitable for use as both a thermal barrier coating for turbine blades and vanes and a thermoelectric generator to power high temperature electronics, high temperature wireless transmitters, and high temperature sensors. Unique to these applications is that the thermal barrier coatings can act as a temperature sensor and/or a source of power for other sensors or high temperature electronics and wireless transmitters.

### PRIORITY INFORMATION

This present application is a continuation of International Patent Application No. PCT/US2007/081778, filed on Oct. 18, 2007, which claims priority to U.S. Provisional Patent Application Ser. No. 60/852,489, filed on Oct. 18, 2006, all of which is incorporated herein in its entirety.

### GOVERNMENT SPONSORSHIP

This invention was made with government support under Grant No. NNC05GA67G awarded by the National Aeronautic and Space Administration (NASA). The government has certain rights in the invention.

### BACKGROUND OF THE INVENTION

In a recent Department of Energy/Oak Ridge National Laboratory report, the needs for sensors and controls for advance turbine systems were assessed and the highest priority need identified was the accurate measurement of combustion gas temperature and flame detection up to 1650° C. to enable closed loop control of emissions. Also identified in this report was the need for the development of durable sensors to control combustion instabilities caused by lean fuel mixtures. Since May 2002, the Propulsion Instrumentation Working Group (PIWG) of the Ohio Aerospace Institute has consistently ranked surface temperature and surface temperature mapping, the highest interest to its members. Based on these assessments, it is clear that temperature measurement is still the most critical measurement in the gas turbine engine environment and the technical challenge becomes more significant as operating temperatures are increased. Improvements in fuel economy and payload capacities (higher capacity airspace systems) is realized by active combustor control. This requires an integrated sensor (temperature sensor) system with a response time that is sufficiently rapid and it allows feedback control to dampen out pressure fluctuations, i.e. microsecond to millisecond response times. The thin film sensors for the hot gas path are fast enough to provide the necessary feedback and robust enough to measure flame temperature and combustor liner temperature distribution.

Durable and accurate thin film thermocouples (TC's) and resistance temperature devices (RTD's) for the direct measurement of temperature and heat flux are being produced. The thin film temperature sensors are based on wide bandgap, semiconducting oxides with indium-tin-oxide (ITO) being the leading candidate material. Over the past few years, efforts to develop a ceramic strain gage based on semiconducting oxides have shown that ITO could be stabilized to temperatures typically encountered in the gas path of turbine engines and could be manufactured in a cost effective and reproducible manner. Recent studies of a variety of semiconducting oxide thermocouples, have indicated that ITO would be ideally suited for gas turbine engines. Preliminary results indicate that by appropriately “doping” ITO films (one thermoelement prepared in an oxygen-rich plasma and another prepared in a nitrogen-rich plasma), ceramic thermocouples could be prepared with a linear thermoelectric response from room temperature to 1500° C. and a Seebeck coefficient of 6 μV/° C. This response was attributed to the difference in charge carrier concentration and resistivity of the individual ITO thermoelements. Here, phonon-phonon and phonon-electron scattering events were responsible for the “classic” behavior observed in these ceramic thermocouples. Other ceramic thermocouples have been considered for gas turbine applications based on silicides, nitrides and carbides but these materials are not thermodynamically stable in air ambients.

An earlier review of candidate materials for temperature measurement to 1650° C. by NASA indicated that materials stability in high temperature environments is the most critical issue for high temperature sensors. Sensor elements based on semi-conductive oxides such as ITO do not undergo any phase changes or reactions with oxygen when thermally cycled between room temperature and the target temperature. The small thermal mass associated with these thin film sensors allows them to be extremely responsive (μs response times) and also permits local temperature measurement without thermal distortion. Pattern factor could be assessed from thermocouple arrays formed on the combustor liner with adequate radial and circumferential resolution, if they could operate reliably in the combustor section of a gas turbine engine (1650° C.) for prolonged periods. Robust ceramic thermocouples are prepared by depositing the thin film thermocouples directly onto ceramic probes comprised of magnesium aluminate spinel, alumina, oxidized silicon carbide or oxidized zirconia and then placing them directly in the gas path.

The performance of the semi-conductive oxide sensors at very high temperatures is dependent on the microstructure developed in the ceramic. For example, it was found that ITO strain sensors prepared in nitrogen-rich plasmas resulted in the metastable retention of nitrogen and actually slowed the sintering and densification kinetics to the point where much finer microstructures were achieved. Average ITO particle sizes were considerably smaller when sputtered in nitrogen-rich plasmas as compared to sensors grown in oxygen-rich plasmas and this ability to grow nanometer-sized ITO particles lead to dramatic improvements in electrical stability at very high temperatures. In addition, when these ITO materials were deposited onto high purity alumina substrates as strain sensors, they survived tens of hours of strain testing at 1580° C. with minimal drift (0.0001%/hr), suggesting that these materials can be further stabilized in the presence of aluminum oxide. The same techniques are applied to control microstructure in the proposed ITO based thermocouples and heat flux sensors. A similar approach has been used to grow dilute nitride semiconductors and recently has received considerable attention in the literature. “Doping” wide bandgap semiconductors with nitrogen leads to considerable bandgap narrowing, enables the electrical properties to be precisely controlled during deposition. Thus, the repeatability and reproducibility of the electromotive force generated in conducting oxide thermocouples as a function of temperature, sensor thickness and resistivity is addressed as well as ways to improve high temperature stability of thin film conducting oxides using these techniques.

Reliable, low cost thin film sensors capable of long-term operation without excessive maintenance are proposed for surface temperature, strain and heat flux measurement in the hot sections of advanced gas turbine engines. The development of propulsion systems employing advanced materials and designs requires the continuous, in-situ monitoring of engine components operating under extreme conditions, since most analytical techniques provide only an estimate of blade/component conditions. Thin film sensors that are capable of providing reliable data within these harsh environments will ultimately be developed for NASA to meet the needs of the gas turbine industry and other end-users. These sensors will also enable system-level integration for the detection of aging-related damage and degradation in future civilian and military aircraft, a primary objective under NASA's Aircraft Aging and Durability (AAD) Project within the Aviation Safety Research Program. Since these harsh environments will greatly affect sensor reliability, lifetime and performance, materials stability at high temperature is the overriding factor in the selection and design of sensors. Thus, robust thin film sensors will play an increasing role in the system-level interrogation of engine components operating at higher temperatures and the outcome of the proposed work will include a list of semi-conductive oxides and nanocomposites for specific sensor applications including composition, deposition parameters, temperature limits, stability and specific test results.

In order to meet the long-term instrumentation needs associated with NASA's Aircraft Aging and Durability (AAD) Project and its associated set of challenge problems (CP-07) related to Durability in Engine Hot Section (AAD-1), semi-conductive oxides and cermets (nanocomposites) will be used as the active sensor elements in temperature, strain and heat flux sensors. Indium tin oxide (ITO) thin films will serve as the sensor platform. ITO films were combined with nanocermets, to produce thin film thermocouples with very large thermoelectric powers. The large thermoelectric responses anticipated will be exploited in thermocouples, heat flux sensors and energy harvesting devices to power active wireless strain gages.

Ultimately, the implementation of the thin film sensors will be placed into the turbine section of gas turbine engines. These sensors will lead to improved reliability and extended performance. For example, the monitoring of temperature distribution and pattern factor in the combustion chamber of a gas turbine engine is critical since the lack of proper fuel burning can severely damage engine components and affect overall performance. The sensors advance the knowledge in the fundamental disciplines of aeronautics and are used to develop technologies for safer aircraft and higher capacity airspace systems. Specifically, advanced thin film instrumentation and associated fabrication methodologies will be developed for improving overall safety of new vehicles operating in the next generation air transportation system.

As the number of sensors is increased on modern gas turbine engines, it is increasingly desirable that the data be transmitted wirelessly. However, the sensors that provide the data and the radios that transmit the data need a source of power. Batteries are impractical because they are difficult to replace and cannot operate at high temperatures, so a local power source is necessary. At the same time, it is desirable to protect engine hot section blades and vanes from the hot combustion gases through use of low thermal conductivity ceramic coatings. The objective of this invention is to provide this thermal protection while at the same time providing power for wireless sensors and high temperature electronics.

### SUMMARY OF THE INVENTION

A nanocomposite cermet thermocouple material having a high voltage output and ultra low thermal conductivity, and is stable in hot oxidizing atmospheres, allowing it to be used as both thermoelectric generator and thermal barrier coating in the hot section of a turbine engine.

The proposed invention replaces the presently used thermal barrier coating material (Yttria stabilized Zirconia) with nano-composite ceramic material on one side of the blade and indium-tin oxide on the other Convective heat transfer from the hot combustion gas to the blade and conductive heat transfer from the outer blade surface to the blade root creates a temperature gradient from the tip of the blade to the root that can be as large as 450° C. Improved thermoelectric materials exploit this temperature difference to produce useable electric power.

The thermal conductivity of these materials is roughly one fifth of the presently used materials, so the thermal protection will be at least as good for a given coating thickness. In addition, preliminary calculations indicate that even for conservative estimates of gas temperature, heat transfer coefficient and root temperature, the open circuit voltage could be over one volt per blade and the power over one milliwatt. The output from the blades can be connected in a series to produce higher voltages. Based on 2D calculations, with a 5 mil layer of nano material (k=0.5 W/m/K) on a 6″1 long×¼″ thick Inconel (k=12 W/m/K) bar, 1200 C. gas temp, 600 C root temp, heat transfer coefficient (h=100 W/m**2/K), the delta T from root to tip is 543 C. With S=850 microvolt/C, the open circuit voltage is 0.46 volts! With an electrical resistivity of 5 E-03 ohm cm, a length of 6″, thickness of 5 mils, and assuming 1″ width, I calculate a resistance of 2.36 ohms. Maximum power delivered to a load occurs when the load and output resistance are equal; the power delivered to a 2.36 ohm load is about 22.5 mW. The high temperature NASA SiC amp takes 40 volts (so 100 blades would have to be strung together in series) to produce microamps of current.

An objective of the present invention is to provide a nanocomposite combined with and ITO to generate nearly 1000 μV/° C. of thermoelectric power such that there is enough energy to harvest.

Another objective is to provide a repeatable, reproducible thermocouple.

Still another objective is to provide a sputtering method of preparing a composite to be used as a nanocomposite in a thermocouple.

These and other objectives and features of the present invention will now be described in greater detail with reference to the accompanying drawings, wherein:

### BRIEF DESCRIPTION OF THE DRAWINGS

FIG. 1 is a graph illustrating the thermoelectric response of a nanocomposite thermoelement relative to platinum with the nanocomposite element sputtered in pure argon (a mtorr);

FIG. 2 is a graph of the first cycle illustrating the response of an ITO, where the ITO is sputtered in N₂ and Ar;

FIG. 3 is a graph of the Seebeck coefficient of the cycle of FIG. 2;

FIGS. 4A-4C are micrographs of cycles 4-6;

FIGS. 5A and 5B are similar test illustrating an ITO prepared in O₂;

FIGS. 6A and 6B are graphs illustrating an ITO prepared in N₂ and Ar;

FIGS. 7A-7C are an additional 3 cycles;

FIG. 8 is an SEM micrograph of a thermally sprayed composite sputtering target (top) consisting of NiCoCrAlY/aluminum nanocomposite and on the bottom is a TEM micrograph of the resulting nanocomposite; and

FIG. 9 is a photograph of the equipment used to prepare the ITO.

### DETAILED DESCRIPTION OF THE INVENTION

Thin film thermocouples are non-intrusive in that the thermocouple thickness is considerably less than the gas phase boundary layer thickness. In addition, platinum and platinum/rhodium based thermocouples are prone to yield errors due to catalytic effects and can give results that can deviate by as much as 50° C. from the actual temperature. Also, thin film thermocouples based on platinum and platinum/rhodium have indicated serious oxidation problems related to the oxidation of rhodium in the temperature range (700-900° C.) and potentially damaging substrate reactions at temperatures above 1250° C. In addition, platinum and platinum/rhodium thermocouple elements are prone to signal drift when used above 1000° C. for prolonged periods due to deterioration of the mechanical properties via creep processes. These alloys are very expensive, even when used in thin film form. Thus, semi-conductive oxide thermocouples represent a cost effective alternative to temperature sensing when compared to conventional precious metal thermocouples.

Recently, nanocomposite (and nanolaminate) thin films have received considerable attention in the literature as thermal barrier coatings since much lower thermal conductivities are possible relative to their coarse grained counterparts: There is considerable potential that this ultra-low thermal conductivity may be combined with high electrical conductivity in the same material to produce an ideal thermoelement for thermocouples and related thermoelectric devices. Thermoelectric devices based on “n-type” (ITO)/metal (nanocomposite) junctions are not only exploited as high temperature thermocouples and heat flux sensors but have considerable potential as thermoelectric generators. Such devices provide enough electrical energy to power active wireless strain gages in remote locations within the gas turbine engine environment. The ITO sensors produced have been characterized as “n-type” based on hot probe and Hall measurements. Based on preliminary experiments using a non-optimized nanocomposite (NiCoCrAlY/alumina) and ITO as thermoelements, Seebeck coefficient's in the range 1200-3000 mV/° C. were realized. Based on these findings, a figure of merit for thermoelectric devices comprised of NiCoCrAlY/alumina and ITO was estimated to be on the order of 10×10-3 IC1, according to equation (1) below:

Z=S²/ρk (1)

where S is the Seebeck coefficient, ρ is the electrical resistivity and k is the thermal conductivity of the elements. This value compares favorably to devices based on thermoelectric semiconductors such as Si_{0.78}Ge_{0.22} which has figure of merit of 056×10⁻³ K⁻¹ and PbTe (p)/PbTe(n) which has figure of merit of 1.3×10⁻³ K⁻¹. In addition, the materials for energy harvesting in the gas turbine engine environment are considerably more stable and oxidation resistant than these semiconductors.

The thin film thermocouples based on reactively sputtered indium-tin-oxide (ITO) and nanocermets measure the surface temperature and heat flux at various locations in the combustor and turbine sections of gas turbine engines and will replace platinum based temperature sensors. As gas turbine engines become more efficient, there is a greater need for spatial and temporal control of the fuel/air ratio at all power settings to reduce harmful emissions while maintaining high performance. It is necessary to measure temperature at specific locations in the flow path and on the combustor liner to determine both radial and circumferential temperature variations in the next generation of propulsion engines. For example, pattern factor can be assessed from thermocouple arrays with adequate radial and circumferential resolution provided that they operate reliably at temperatures approaching 1650° C. for prolonged periods. Such measurements will be used in conjunction with thin film heat flux sensors based on the same materials to complement pattern factor measurements.

The nanocomposite thermoelements are based on optimal combinations of refractory metals dispersed in oxide matrices. These nanocomposites are attractive in that they possess the properties of ceramics such as thermal stability and oxidation resistance, while the refractory metals provide electrical conductivity. The large number of interfaces of essentially different constituent materials (different elastic moduli) can result in ultra low-thermal conductivities. Using combinatorial chemistry as a screening method to determine the optimal ratio of metal and oxide in the nanocomposite, a series of candidate thermoelements relative to platinum are being tested under laboratory conditions to establish the thermoelectric response.

Based on these results, thermal sprayed sputtering targets will be fabricated from the most promising nanocomposite thermoelements. The ceramic matrices to be investigated for this purpose include: Al₂O₃—MgO and Al₂O₃ and the refractory metals include NiCoCrAlY, NiCrAlY, Pt and W. Optimized bi-ceramic junctions were tested in laboratory environments using computer controlled burner rig and NASA's atmospheric burner rigs to simulate the combustion section of the gas turbine engine.

Nanocomposite strain gages with near zero TCR were designed. Refractory metal phases having characteristic sizes on the order of nanometers are embedded in a ceramic matrix (ITO) using non-equilibrium physical vapor deposition processes. The large surface area to volume ratio along with the optimal phase distribution produce metallic phases with dimensions smaller than the mean free path for electrons and thus, electron scattering will occur largely at grain boundaries. As a result, the electrical resistivity and temperature coefficient of resistance (TCR) are greatly affected by the distribution of phases in the nanocomposite, since electrical conduction in ITO is also governed by grain boundaries as well.

Combinatorial chemistry was used as the screening method to determine the optimum ratio of metallic and semi-conductive oxide phases.

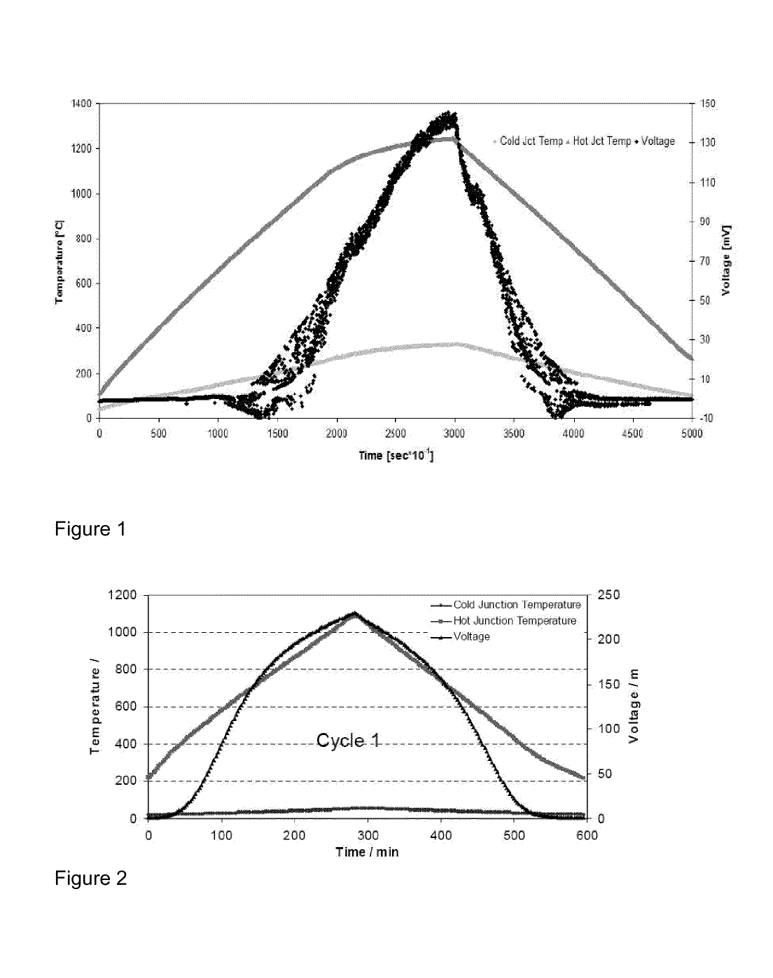

Thermal sprayed sputtering targets are fabricated from the most promising combinatorial libraries. Part of the focus on the development of nanocermets is to use combinatorial chemistry as a screening method to determine the composition of the most responsive thermoelements relative to platinum. Based on the results, thermal sprayed sputtering targets is fabricated from which new nanocomposite thermocouples will be formed. Al₂O₃—MgO and Al₂O₃ were considered for the oxide matrices and NiCoCrAlY, NiCrAlY, and Pt and W were considered for the metallic phases. Combinatorial chemistry is used to develop nanocomposite coatings with low thermal conductivity to reduce thermal stresses and oxidation of the underlying bond coats in TBC's. Similar techniques were used to investigate a wide range of compositions for the purpose of optimizing the thermoelectric power and high temperature stability of the most promising nanocermets. The thermoelectric response of a non-optimized nanocermet/ITO thermocouple is shown in FIG. 1 is the thermoelectric response of a nanocomposite/pt thermocouple wherein the nanocomposite was prepared in pure argon.

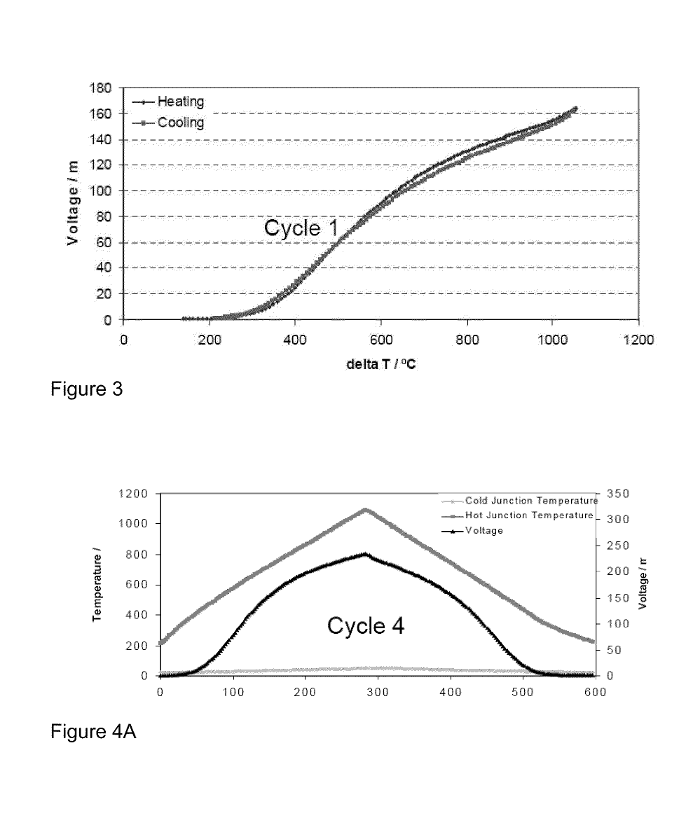

As shown in FIGS. 2 and 3, the nanocomposite is one thermocouple leg and the other thermocouple leg is an ITO but both are sputtered. Illustrated in the graph is the first cycle of a nanocomposite ITO thermocouple. In the first cycle one ramps up the temperature then the temperature is ramped down. The voltage response is shown when the results are plotted as a function of the ΔT and it that gives the Seebeck coefficient, thus showing little or no hysteresis.

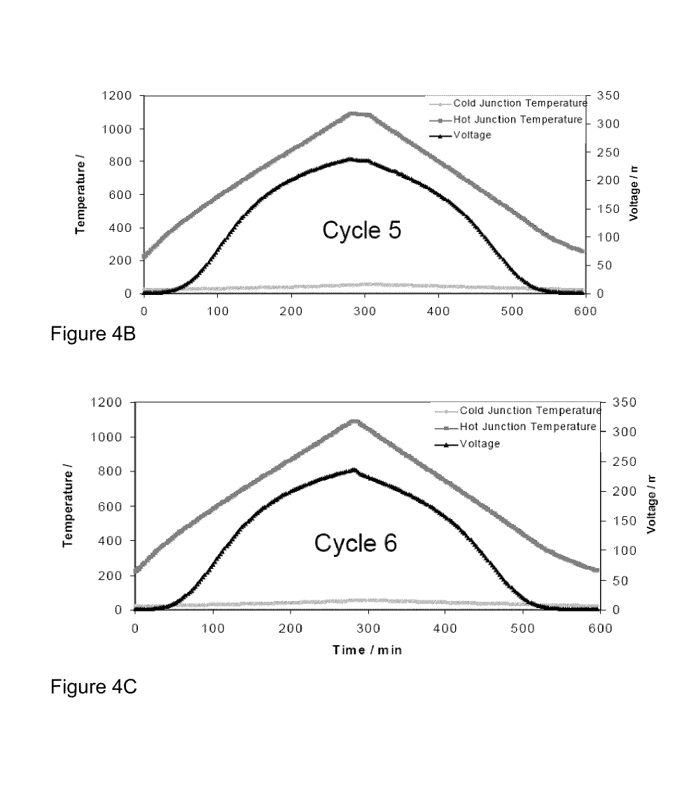

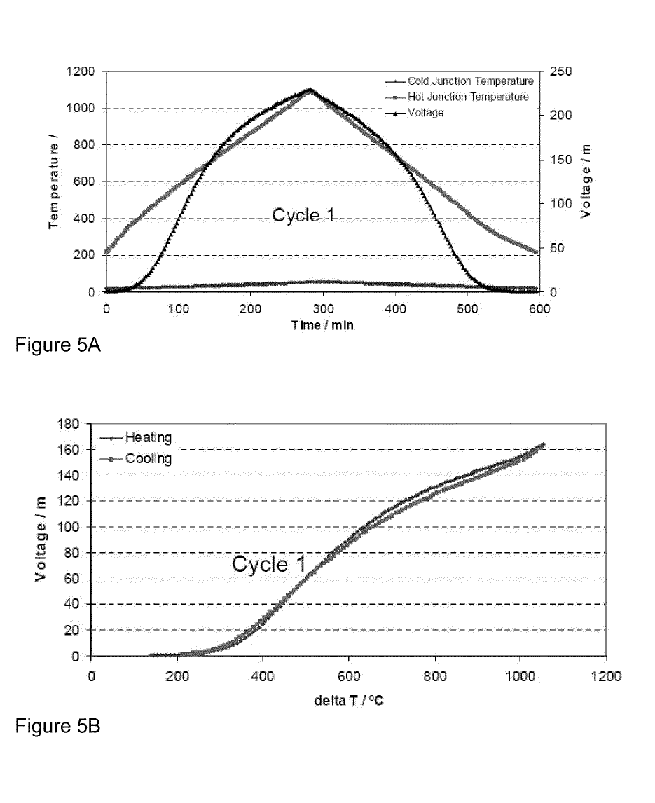

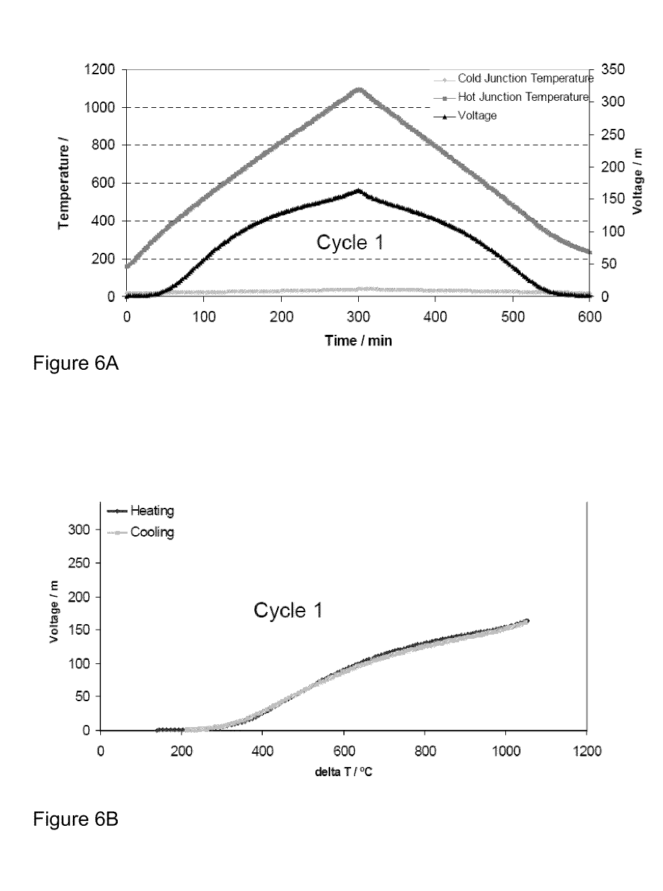

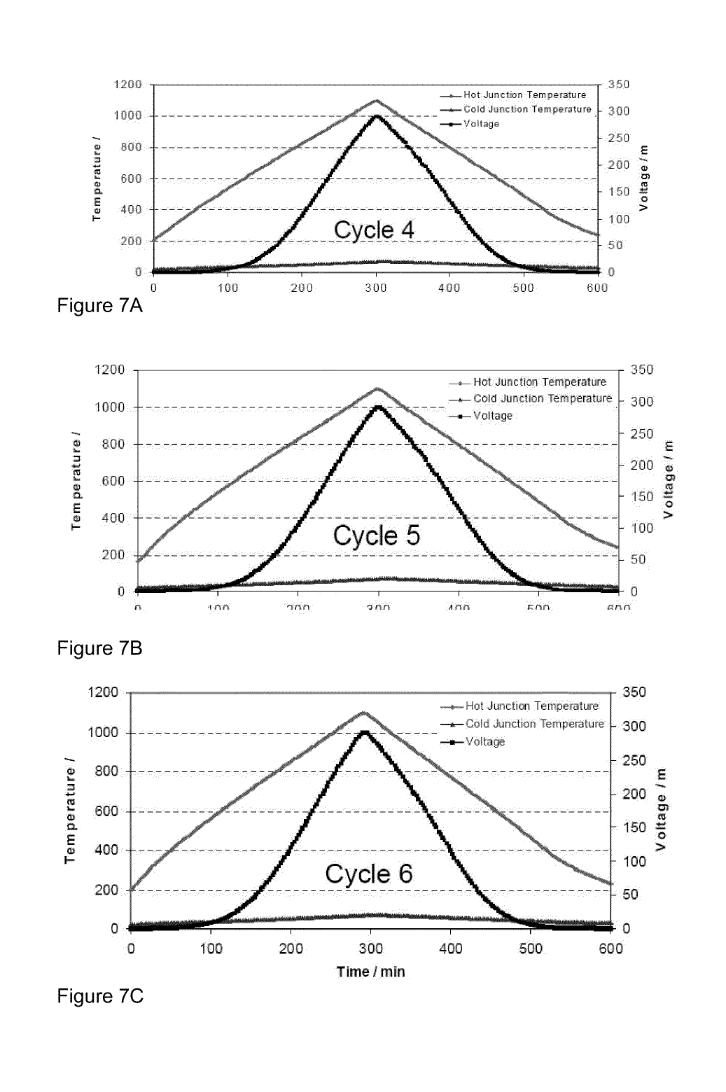

FIGS. 4A-C are additional cycles of the test in FIG. 1. The graphs show the repeatability of the ITO. FIGS. 5A and 5B show similar results for an ITO prepared in O₂. FIG. 4B shows an increase in the Seebeck coefficient. FIGS. 6A and 6B illustrate similar results wherein the ITO was prepared in Nitrogen and Ar. Again, the Seebeck coefficient increases. FIG. 7A-7C are additional cycles illustrating the repeatability of the increase.

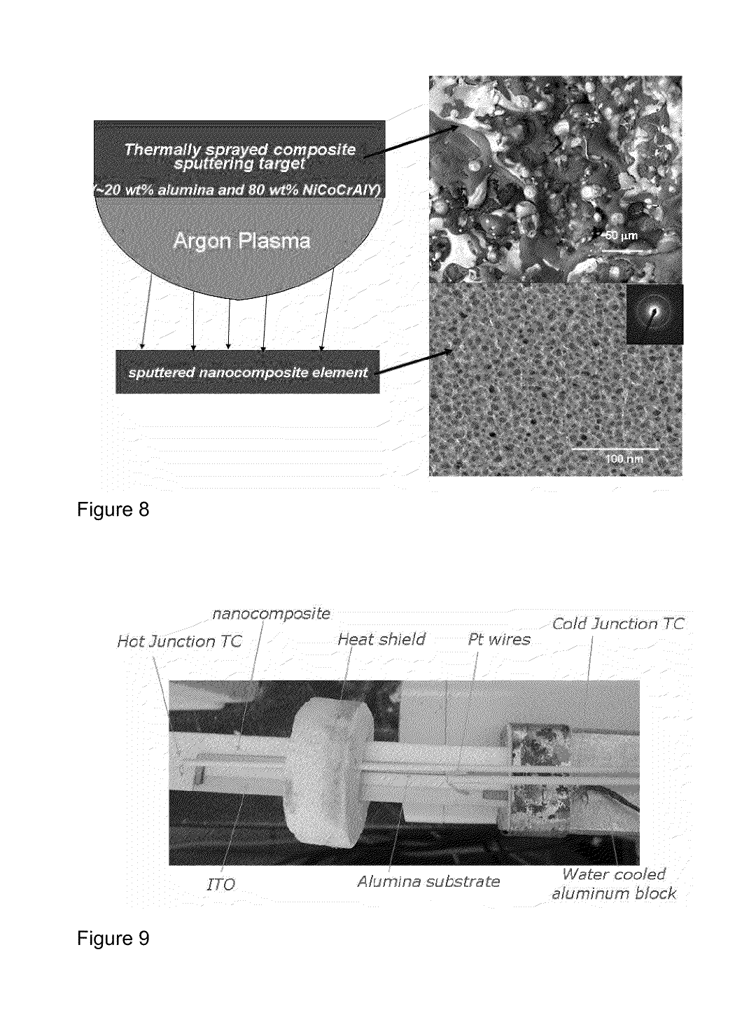

Combinatorial libraries of thermoelements were prepared by co-sputtering refractory metals and oxides through shadow masks to form nanocomposites over a wide range of composition on alumina substrates. The substrates are located between a refractory metal and alumina or magnesium aluminate target. The deposited coating is segmented into well-defined areas on the substrate via a shadow mask. Thus, a gradation of composite compositions is produced, depending on the distance from each target. Each library is comprised of a composite thermoelement deposited onto a platinum element and the resulting thermocouples will be thermally cycled to 1650° C. The thermoelectric power of each library was evaluated by localized heating and the compositions with the largest thermoelectric power and the most stable and responsive thermoelements selected for further investigation. The libraries showing the most promise in terms of thermoelectric power and stability at temperature were analyzed for chemical composition by SEM with energy dispersive analysis of x-rays (EDS) and electron spectroscopy for chemical analysis (ESCA). Those compositions were then selected as starting points for preparing thermal sprayed composite targets. The very different length scales of the microstructural features in the sputtering target relative to those in the sputtered nanocomposite are shown in FIG. 8.

With the nanocomposite combined with the ITO nearly 1000 microvolts per degree C. of thermoelectric power can be generated which is significant enough to do energy harvesting. One can generate electrical power remotely based on the temperature gradients of, for example, a gas turbine engine. Thus, one can use that energy to power wireless electronic circuits on blades and inside the turbine engine environment so that one can do active wireless measurements.

The top is a SEM micrograph of a composite thermospray material, the light color phase in that micrograph above is the NiCoCrAlY and the dark color is the aluminum oxide and the opposite is true in the micrograph below. The magnification in the top is about 100× wherein the magnification below is 200,000×. The top looks like melting has occurred because it was thermosprayed. These particles are mixed in the appropriate ratio and sprayed out so that they are melted. The temperature of the plasma coining out there is about 3,000 centigrade. The nanocomposite is formed by taking the material in a cold state and in the form of a disk and sputtering it. The microstructure changes by 3 or 4 orders of magnitude in scale it is sputter it that is the novel and creative part when you sputter it. You take very course, very rough composite material and sputter the material in this non-equilibrium process and it becomes a nanostructure material.

HPI Inc., of Ayer, Mass., has the unique capability to add small amounts of powder of the desired composition to alumina or magnesium aluminate spinel powder comprising the feed and produce composites with larger scale but very uniform distribution of phases. Several iterations were necessary to adjust the spraying parameters to account for differences in microstructure. SEM was used to characterize the microstructure and morphology of the thermal sprayed composite material to be used as targets. Glancing angle X-ray diffraction and transmission electron microscopy (TEM) was used to determine the crystalline nature and phase content of the deposited nanocomposites. The thin film sensors on alumina or magnesium aluminate spinel substrates as well as selected TBC's will be completely characterized in terms of performance including drift and thermoelectric response during the course of thermal cycling from 25° C. to 1650° C. The thin film thermocouples was calibrated against standard type S thin film thermocouples, fabricated adjacent to the hot and cold junctions to establish precise values for the thermoelectric power.

To fabricate thin film sensors on superalloys, extensive work has been done at the University of Rhode Island to form stable passivation and diffusion barrier layers, which provide electrical and chemical isolation. This includes the heat treatment of Al₂O₃ coated NiCoCrAlY surfaces in reduced O₂ partial pressures. The nanocomposites proposed within were based on cermets or more precisely nanocermets with metallic phases having characteristic sizes on the order of nanometers embedded in a ceramic matrix. The large surface area to volume ratio results in a metallic phase which has dimensions smaller than the mean free path for electrons and thus, electron scattering will occur largely at grain boundaries. As a result the resistivity is greatly affected by distribution of phases in the nanocomposite.

Indium-tin-oxide based sensors are much more stable than the carbides and nitrides when subjected to oxidizing atmospheres at elevated temperature. The sensors were built upon the past accomplishments of NASA supported research. Specifically, one of the proposed sensors was built upon the concept of a self-compensated strain gage developed under prior NASA support where platinum resistors were placed in series with ITO strain gages to produce a near zero TCR. By controlling the distribution of the same materials in a nanocomposite, a thin film strain gage with a near zero TCR was achieved by direct deposition onto an engine component A similar outcome of the effort is for the ITO/nanocomposite thermocouples that exhibit very large Seebeck coefficients. These sensors were built upon the concept of an all-ceramic (all ITO) thermocouple that was to enable the integration of a thin film strain gage and temperature sensor with a minimal number of deposition steps. By controlling the distribution of metal and alumina in the nanocomposite, an optimized thermoelement in combination with ITO, yielded Seebeck coefficients that are large enough for thermocouples/energy harvesting devices to power active wireless strain gages. Once again, the deposition parameters including power density, target composition, partial pressures, etc. is the strategic outcome. The thin film instrumentation contributes to the goals of project, specifically by adding to the knowledge base in aeronautics and developing technologies that permit new engine materials to be characterized, structural models to be validated, and component performance data to be compiled to assist design engineers in making safer aircraft and higher capacity airspace systems.

Additionally, the design, development and fabrication of sensor arrays based on semi-conductive oxide/nanocomposite thermocouples (and related thermoelectric devices) and semi-conductive oxide heat flux sensors will be possible for the first time. The remaining work will focus on the characterization and subsequent testing of the semi-conductive oxide sensors.

High density ITO targets with a nominal composition of 90 wt % In₂0₃ and 10 wt % SnO₂ were used for the ITO depositions and a high purity platinum target was used for all platinum depositions including those for thin film leads and bond pads. Two MRC model 822 sputtering systems were dedicated to the deposition of semi-conducting oxides, NiCoCrAlY:Al₂0₃ nanocomposites, platinum and platinum/rhodium based films. An MRC model 8667 was used for all combinatorial chemistry experiments, since the rf power can be distributed among 2 or 3 sputtering targets simultaneously. Oxygen and nitrogen partial pressures ranging from 5-50% were maintained in the sputtering chamber using an MKS mass flow controlled delivery system and an if power densities of 1-4 W/cm² was used for the sputtering runs. Thick platinum films (3-5 μm thick) was used to form ohmic contacts to the ITO and NiCoCrAlY:Al₂0₃ nanocomposite thermoelements. Platinum lead wires were welded to platinum bond pads using either parallel gap welding or laser welding. Type S thin film thermocouples were formed adjacent to the hot and cold junctions of the ceramic thermocouples, using a 90% platinum-10% rhodium sputtering target in conjunction with the pure platinum target. After deposition of the semi-conductive oxide and metallic thin films, a subsequent heat treatment step in nitrogen was required to densify the films, reduce point defects and remove any argon gas trapped in the films during sputtering. If this heat treatment step is omitted, rapid heating of the films to high temperatures could cause any trapped argon to coalesce and form bubbles within the films, which could eventually lead to rupture.

A combinatorial chemistry approach was used to investigate a range of compositions for the purpose of improving the thermoelectric power and electrical stability of the semi-conductive oxide/nanocomposite thermocouples. Specifically, one was to prepare specimens by co-sputtering from NiCoCrAlY (or NiCrAlY) and high purity alumina targets to produce nanocomposites varying composition onto polished alumina substrates. The substrates were located between an NiCoCrAlY (or NiCrAlY) target and an aluminum oxide target. The deposited coaling was segmented into well-defined areas on the substrate via a shadow mask such that continuously graded compositions was produced, depending on the distance from each target. The MRC 8667 sputtering machine was capable of co-sputtering from two or three targets simultaneously. This system allowed mixing of the materials in the plasma to create a range of compositions. Small platinum leads were sputtered onto each segmented area using a different shadow mask and the thermoelectric response of each library was measured by localized heating and the compositions with the largest thermoelectric power and the most stable response will be selected for further investigation. Those compositions were then used as starting points for preparing sputtering targets by thermal spraying techniques. Glancing angle X-ray diffraction (Scintag Diffractometer) was used for phase analysis and scanning electron microscopy (JEOL JSM-5900LV SEM with light element EDS) was used for chemical analysis of the most promising combinatorial libraries and final thermal sprayed sputtering targets.

The thermoelectric response and drift of the ITO/NiCoCrAlY:Al₂0₃ and platinum/NiCoCrAlY:Al₂0₃ thermocouples was measured at different temperatures by placing a heat shield in between the hot and cold junctions of the ceramic thermocouple, such that a constant temperature gradient was imposed along the ceramic substrate. The thickness of the heat shield was used to determine the magnitude of the imposed gradient and a specially designed water-cooled heat sink was also used to clamp the ceramic substrates at the cold junction to insure a constant temperature for the reference condition. The dissimilar semi-conducting oxide and NiCoCrAlY:Al₂0₃ films were sputtered onto 7 inch long alumina substrates to form the bi-ceramic junctions at one end and the bond pads at the other end (cold junction). Sputtered platinum films were used to form ohmic contacts to the thermoelement leads. The voltage output from the thermocouples was monitored using a USB data acquisition system (Personal DAQ 54 by I/O Tech) and associated software (Personal DaqView) for continuous data acquisition purposes. The libraries showing the most promise in terms of TCR and electrical stability at temperature were analyzed for chemical composition by SEM/EDS and ESCA. Those compositions were then used as starting points for preparing thermal sprayed composite targets by adding small amounts of the refractory metal powder to the ITO powder.

There is a great desire and need to develop compositions that, when thermally sprayed, will give similar results to those of the sputtered nanocomposite coatings. Once prepared, the nanocomposite thermocouples will be assembled onto appropriate hardware and tested.

Heat flux sensors based on ITO and NiCoCrAlY:Al₂0₃ can also be prepared by fabricating thin film thermocouple's next to one another. They will be designed in such a way that one thermocouple will be covered with a thermal barrier such as alumina and the other thermocouple will be unprotected. In this way, the difference in signals from these two thermocouples can be related to the heat flux provided that the thermal conductivity of the protective alumina coating is well characterized. These heat flux sensors will be fabricated on a variety of substrates including TBC's.

Since the heat flux sensors and strain gages require relatively small footprints to achieve point measurements, these sensors will be fabricated by photolithography techniques. The fabricating thin film sensors may be accomplished on curved turbine blades. Prior to deposition, the substrates will be placed in an oxygen:argon plasma (Technics Plasma Gmbh) for 30 min to remove all organic residue. To delineate the desired-sensor patterns for the ITO, NiCoCrAlY:Al₂0₃ nanocomposite on the alumina coated substrates, a lift-off process employing a bilevel polyimide-based photoresist (MicroChem. Inc.) and a conventional positive photoresist (AZ 4400) will be used. This modified lift-off process allows both ceramic films such as ITO and nanocomposite to be if sputtered through windows created in the resist without damaging the resist. The underlying polyimide resist is more thermally stable than conventional positive resists making it capable of withstanding prolonged exposure to the if plasma and associated heating effects. This process is capable of submicrometer resolution and liftoff is greatly facilitated by the enhanced thickness of the bi-level resist layer and associated undercutting of the polyimide layer during the developing process. A photomask with the desired artwork will be placed over the resist-coated substrate and exposed to UV light to create the desired pattern. At this point the image will be developed using an AZ developer, which will dissolve both layers of exposed resist, undercutting the polyimide in the process. Once developed, films consisting of ITO, nanocomposite or platinum will be sputtered through the windows created in the resist-coated substrate. After deposition, the final device structure will be delineated by placing the substrate in an acetone bath to remove the positive resist layer and then placed in the polyimide shipper (Microchem Nanoremover) to remove the excess polyimide films.

Although the present invention has been shown and described with respect to several preferred embodiments thereof, various changes, omissions and additions to the form and detail thereof, may be made therein, without departing from the spirit and scope of the invention.

What is claimed is:

1. A nano-composite material having high electrical conductivity and high Seebeck coefficient and low thermal conductivity, capable of withstanding high temperatures and harsh conditions, which properties make it suitable for use as both a thermal barrier coating for turbine blades and vanes and a thermoelectric generator to power high temperature electronics, high temperature wireless transmitters, and high temperature sensors, such that the thermal barrier coatings are a temperature sensor and/or a source of power for other sensors or high temperature electronics and wireless transmitters.

2. A device capable of generating approximately 1000 μV/° C. of thermoelectric power such that said energy can be harvested; said device comprising a nanocomposite combined with an indium tin oxide thermoelement such that said device generates electrical power from an engine.

3. Thermocouples combined in a series to form a thin film thermopile such that said thermopile is a heat flux sensor and is usable to measure heat flux across a thermal barrier coating applied to turbine blades.

4. The device of claim 1 wherein the engine is a gas turbine engine.

5. A thermocouple device, wherein said device is responsive and wherein the device is repeatable and reproducible;
said thermocouple comprises a first leg of ITO, ITO₂, or zinc oxide doped with aluminum oxide;
a second leg is a composite sputter coated from a mixture of NiCoCrAlY and Al₂O₃.

6. A method of forming a thermocouple having repeatable, reproducible results, said method comprises:
providing a plate;
thermal spraying said plate at thousands of degrees with a mixture of powders, to form a thermocouple leg;
sputtering; and
providing another leg of indium tin oxide.

7. The method of claim 4, wherein the plate is stainless steel.

8. The method of claim 4, wherein said powders are aluminum oxide and NiCoCrAlY.

9. The method of claim 4, wherein the plate is sputtered sprayed in a vacuum chamber of a sputtering machine.

10. A thin film sensor, said sensor measures surface temperature, strain and heat flux in hot sections of gas turbine engines, said thin film sensor comprising:
nanocomposite thermoelements comprising an oxide matrices having refractory metals dispersed therein.

11. The thin film sensor of claim 1 wherein the oxide matrices are selected from Al₂O₃—MgO and Al₂O₃ and the refractory metals are selected from NiCoCrAlY, NiCrAlY, Pt and W.

12. A method to prepare nanocomposite strain gages having near zero TCR said method comprising vapor depositing nanometer sized refractory metal phases on a ceramic matrix.

13. Using combinatorial chemistry to determine the optimum ration of metallic and semi-conductive oxide phases to form low TCR thin film strain gages.
